(19) United States
(12) Patent Application Publication
(10) Pub. No.: US 2026/0214799 A1
(43) Pub. Date: Jul. 23, 2026

(54) SUBSTRATE AND METHOD OF MANUFACTURING THE SAME

(71) Applicant: CHIPBOND TECHNOLOGY CORPORATION, Hsinchu City (TW)

(72) Inventors: Lung-Hua Ho, Hsinchu City (TW); Chih-Ming Kuo, Hsinchu County (TW); Kung-An Lin, Hsinchu City (TW); Chun-Ting Kuo, Kaohsiung City (TW)

(21) Appl. No.: 19/328,395

(22) Filed: Sep. 15, 2025

(30) Foreign Application Priority Data
Jan. 21, 2025 (TW) 114102606

(51) Int. Cl. H05K 1/11; H05K 1/02; H05K 3/18; H05K 3/42

(52) U.S. Cl. CPC H05K 1/115; H05K 1/0298; H05K 1/113; H05K 3/18; H05K 3/429; H05K 2201/09481; H05K 2201/09563

(57) ABSTRACT

A substrate includes a first dielectric layer, a first conduction layer, a first conductive material, a second dielectric layer, a second conduction layer and a second conductive material. The first conduction layer and the first conductive material which are formed in the first dielectric layer and the second conduction layer and the second conductive material which are formed in the second dielectric layer become a stack via. During manufacturing, dielectric material of the first and second dielectric layers will not remain in the stack via to block electrical connection between the first conductive material and the second conduction layer. Furthermore, contact area of the first conduction layer and the first conductive material and contact area of the second conduction layer and the second conductive material can satisfy specification requirement for electrical transmission.

### CROSS-REFERENCE TO RELATED APPLICATIONS

This application claims priority to R.O.C Patent Application No. 114102606 filed Jan. 21, 2025, the disclosure of which is hereby incorporated by reference in its entirety.

### FIELD OF THE INVENTION

This invention relates to a substrate having a stack via and a method of manufacturing the same, and more particularly to a substrate and its manufacturing method able to avoid dielectric material from being left over in the stack via.

### BACKGROUND OF THE INVENTION

In the conventional method of manufacturing a substrate having a stack via, a first through hole is formed in a first dielectric layer through photolithography technology (exposure and development processes), a first conductive material, such as a redistribution layer (RDL), is formed in the first through hole, a second dielectric layer is provided to cover the first dielectric layer and the first conductive material, a second through hole showing the first conductive material is formed in the second dielectric layer through photolithography, and a second conductive material is formed in the second through hole to be electrically connected to the first conductive material.

However, UV light may penetrate the second dielectric layer not covered by a mask to the first conductive material during exposure process, and dielectric residues may leave on the first conductive material to cause electrical connection failure of the first and second conductive materials.

### SUMMARY OF THE INVENTION

One object of the present invention is to provide a substrate having a stack via and its manufacturing method, dielectric material will not be remained in the stack via of the substrate.

A method of manufacturing a substrate of the present invention includes the steps as follows. (a) forming a first dielectric layer having a first bottom surface, a first top surface and a first through hole, the first through hole has a first opening, a second opening and a first ring wall, the first opening is adjacent to the first bottom surface, the second opening is visible on the first top surface, and the first ring wall is located between the first and second openings; (b) forming a first conduction layer on the first top surface of the first dielectric layer and in the first through hole of the first dielectric layer, the first conduction layer includes a first bottom portion, a first ring portion and a first space, the first bottom portion is in the first opening, the first ring portion is located on the first ring wall and surrounds the first space; (c) forming a first photoresist layer on the first conduction layer and patterning the first photoresist layer, the patterned first photoresist layer has a first filling hole, and the first bottom portion, the first ring portion and the first space of the first conduction layer are visible from the first filling hole; (d) forming a first conductive material in the first space, the first conductive material has a first conduction surface and a second conduction surface, and the first conduction surface is electrically connected to the first bottom portion of the first conduction layer; (e) removing the patterned first photoresist layer; (f) using the first conductive material as a mask to remove the first conduction layer not covered by the first conductive material; (g) forming a second dielectric layer on the first dielectric layer to cover the first dielectric layer, the second dielectric layer has a second bottom surface, a second top surface and a second through hole which is located above the first through hole, the first conductive material is visible from the second through hole, the second through hole has a third opening, a fourth opening and a second ring wall, the third opening is located between the second opening of the first through hole and the fourth opening and is adjacent to the second bottom surface, the fourth opening is visible on the second top surface, the second ring wall is located between the third and fourth openings, and a width of the third opening is less than that of the first opening of the first through hole; (h) forming a second conduction layer on the second top surface of the second dielectric layer and in the second through hole of the second dielectric layer, the second conduction layer includes a second bottom portion, a second ring portion and a second space, the second bottom portion is located in the third opening of the second through hole and is electrically connected to the first conductive material, the second ring portion is located on the second ring wall and surrounds the second space; (i) forming a second photoresist layer on the second conduction layer and patterning the second photoresist layer, the patterned second photoresist layer has a second filling hole, and the second bottom portion, the second ring portion and the second space of the second conduction layer are visible from the second filling hole; (j) forming a second conductive material in the second space, the second conductive material has a third conduction surface and a fourth conduction surface, and the third conduction surface is electrically connected to the second bottom portion of the second conduction layer; (k) removing the patterned second photoresist layer; (l) using the second conductive material as a mask to remove the second conduction layer not covered by the second conductive material. The first conduction layer, the first conductive material, the second conduction layer and the second conductive material become a stack via.

A substrate of the present invention includes a first dielectric layer, a first conduction layer, a first conductive material, a second dielectric layer, a second conduction layer and a second conductive material. The first dielectric layer has a first bottom surface, a first top surface and a first through hole, the first through hole has a first opening, a second opening and a first ring wall. The first opening is adjacent to the first bottom surface, the second opening is visible on the first top surface, and the first ring wall is located between the first and second openings. The first conduction layer is formed in the first through hole and includes a first bottom portion, a first ring portion and a first space. The first bottom portion is in the first opening of the first through hole, and the first ring portion is located on the first ring wall and surrounds the first space. The first conductive material is formed in the first space of the first conduction layer and has a first conduction surface and a second conduction surface, and the first conduction surface is electrically connected to the first bottom portion of the first conduction layer. The second dielectric layer covers the first dielectric layer and has a second bottom surface, a second top surface and a second through hole. The second through hole is located above the first through hole of the first dielectric layer and has a third opening, a fourth opening and a second ring wall. The third opening is located between the second opening of the first through hole and the fourth opening and is adjacent to the second bottom surface, and the fourth opening is visible on the second top surface. The second ring wall is located between the third and fourth openings, and a width of the third opening is less than that of the first opening. The second conduction layer is formed on the second top surface of the second dielectric layer and in the second through hole of the second dielectric layer. The second conduction layer includes a second bottom portion, a second ring portion and a second space, the second bottom portion is in the third opening of the second through hole and is electrically connected to the first conductive material, the second ring portion is located on the second ring wall and surrounds the second space. The second conductive material is formed in the second space of the second conduction layer and has a third conduction surface and a fourth conduction surface. The third conduction surface is electrically connected to the second bottom portion of the second conduction layer. The first conduction layer, the first conductive material, the second conduction layer and the second conductive material become a stack via.

In the present invention, dielectric material will not leave in the stack via to cause electrical connection failure of the first conductive material and the second conduction layer, and contact area of the first conduction layer and the first conductive material and contact area of the second conduction layer and the second conductive material can satisfy specification requirement of electrical transmission.

### BRIEF DESCRIPTION OF DRAWINGS

FIGS. 1A to 14B are cross-section view diagrams illustrating a method of manufacturing a substrate having a stack via in accordance with one embodiment of the present invention.

### DETAILED DESCRIPTION OF THE INVENTION

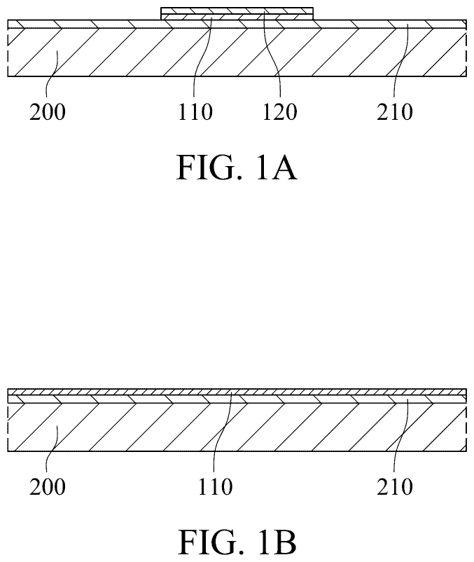

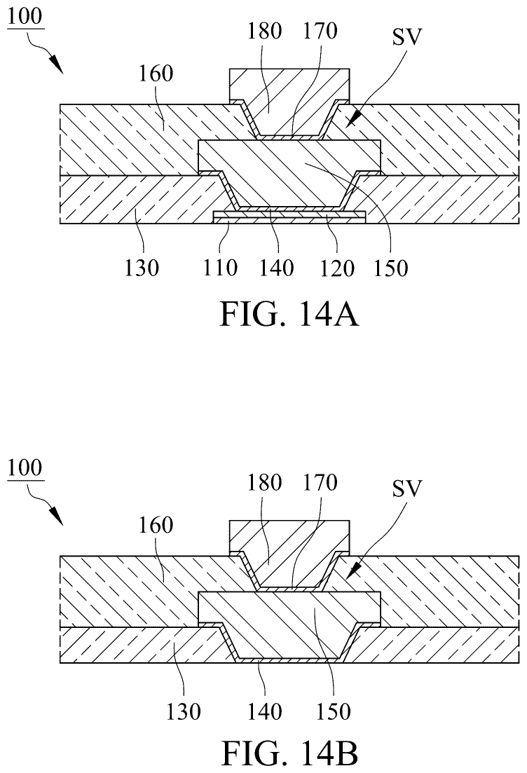

FIGS. 1A to 14B are cross-section view diagrams provided to illustrate a method of manufacturing a substrate 100 of the present invention. As shown in FIG. 14A or 14B, a first conduction layer 140, a first conductive material 150, a second conduction layer 170 and a second conductive material 180 are stacked to become a stack via SV in a first dielectric layer 130 and a second dielectric layer 160.

With reference to FIG. 1A or 1B, a carrier 200 having an adhesive layer 210 is provided firstly, and the carrier 200 may be a wafer or a glass. As shown in FIG. 14A or 14B, the carrier 200 and the adhesive layer 210 are removed after forming the substrate 100.

With reference to FIGS. 1A, 13A and 14A, in a first embodiment of the present invention, a conduction layer 110, which may be under-bump metallization (UBM), is formed on the adhesive layer 210, and a circuit layer 120, which may be a redistribution layer (RDL), is formed on the conduction layer 110. The circuit layer 120 is electrically connected to the conduction layer 110, and after forming the stack via SV, the conduction layer 110 and the circuit layer 120 are retained on the substrate 100 and they are electrically connected to the stack via SV. The conduction layer 110 is provided to be electrically connected to an electronic component (not shown, e.g. a chip or another substrate), and preferably, the conduction layer 110 and the circuit layer 120 are two patterned metal layers.

With reference to FIGS. 1B, 13B and 14B, in a second embodiment of the present invention, the conduction layer 110 is a ground layer used for plating process, and the conduction layer 110, the carrier 200 and the adhesive layer 210 are removed after forming the stack via SV.

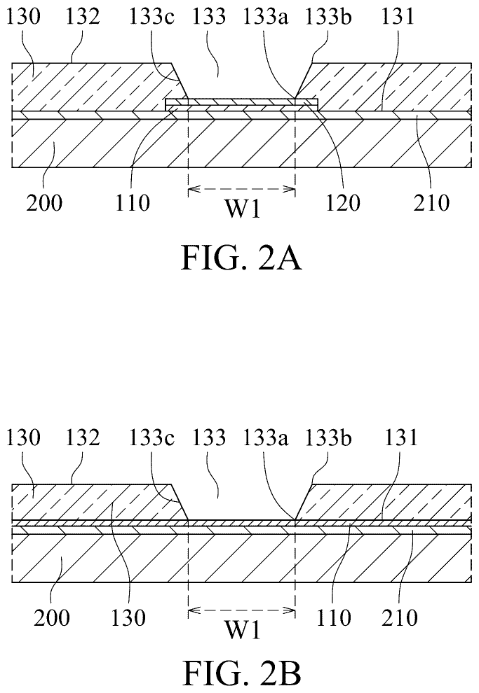

With reference to FIG. 2A, the first dielectric layer 130 is formed on the adhesive layer 210 in the first embodiment. The first dielectric layer 130 may be made of polyimide (PI) or other dielectric materials, and it may be formed on the adhesive layer 210 by coating. The first dielectric layer 130 has at least one first through hole 133 which may be formed through photolithography, and the circuit layer 120 is visible from the first through hole 133.

With reference to FIG. 2B, the first dielectric layer 130 is formed on the conduction layer 110 in the second embodiment, and the conduction layer 110 is visible from the first through hole 133 of the first dielectric layer 130.

With reference to FIGS. 2A and 2B, the first through hole 133 of the first dielectric layer 130 has a first opening 133a, a second opening 133b and a first ring wall 133c. The first opening 133a is close to a first bottom surface 131 of the first dielectric layer 130, the second opening 133b is visible on a first top surface 132 of the first dielectric layer 130, and the first ring wall 133c is located between the first opening 133a and the second opening 133b. Preferably, the first ring wall 133c located between the first opening 133a and the second opening 133b is oblique in cross-sectional view.

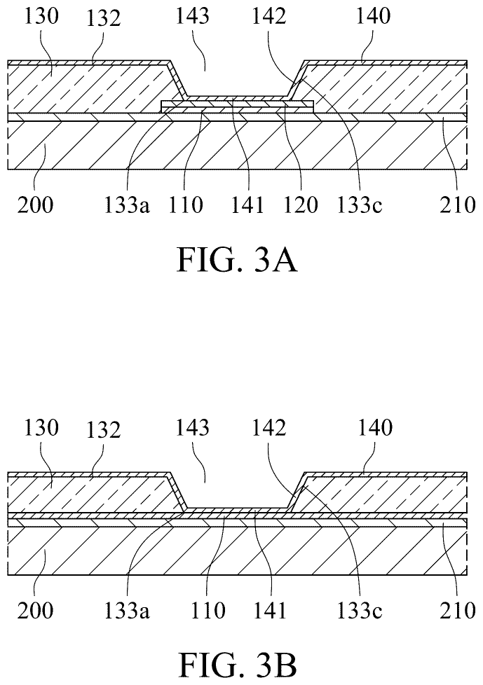

With reference to FIGS. 3A and 3B, after forming the first dielectric layer 130, the first conduction layer 140 is formed on the first top surface 132 of the first dielectric layer 130 and in the first through hole 133 of the first dielectric layer 130. The first conduction layer 140 may be deposited on the first dielectric layer 130 by sputtering. The first conduction layer 140 at least includes a first bottom portion 141, a first ring portion 142 and a first space 143. The first bottom portion 141 is in the first opening 133a, the first ring portion 142 is located on the first ring wall 133c and surrounds the first space 143. Preferably, the first ring portion 142 formed on the first ring wall 133c is oblique in cross-sectional view.

With reference to FIG. 3A, in the first embodiment, the circuit layer 120 is located between the first bottom portion 141 of the first conduction layer 140 and the conduction layer 110 and it is electrically connected to the first bottom portion 141 of the first conduction layer 140.

With reference to FIG. 3B, in the second embodiment, the conduction layer 110 is located between the first bottom portion 141 of the first conduction layer 140 and the adhesive layer 210 and it is electrically connected to the first bottom portion 141 of the first conduction layer 140.

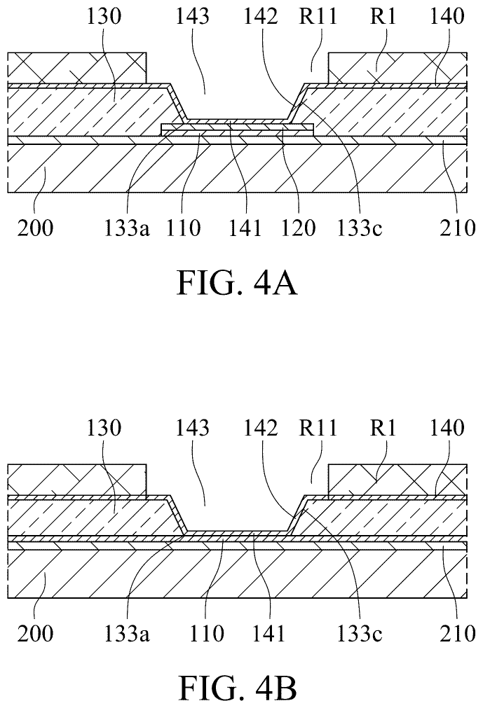

With reference to FIGS. 4A and 4B, after forming the first conduction layer 140, a first photoresist layer R1 is formed on the first conduction layer 140 and then patterned. Photoresist material may be coated on the first conduction layer 140 to form the first photoresist layer R1 covering the first conduction layer 140, and the first photoresist layer R1 may be patterned to have a first filling hole R11 through photolithography. The first bottom portion 141, the first ring portion 142 and the first space 143 of the first conduction layer 140 are visible from the first filling hole R11.

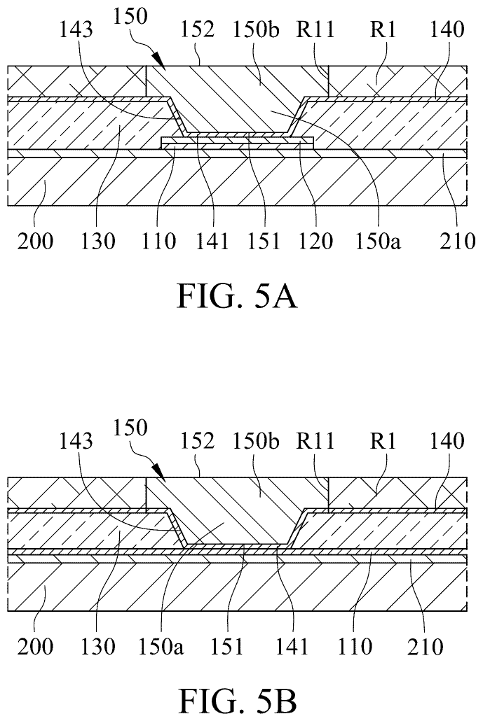

With reference to FIGS. 5A and 5B, after patterning the first photoresist layer R1, the first conductive material 150 is formed in the first space 143 of the first conduction layer 140. The first conductive material 150 may be a part of a redistribution layer (RDL, not shown) formed by plating process. The first conductive material 150 has a first conduction surface 151 and a second conduction surface 152, and the first conduction surface 151 is electrically connected to the first bottom portion 141 of the first conduction layer 140. Preferably, the first conductive material 150 involves a first conductive portion 150a and a second conductive portion 150b, the first conductive portion 150a is located in the first space 143 of the first conduction layer 140, and the second conductive portion 150b is located in the first filling hole R11 of the patterned first photoresist layer R1. In the first embodiment as shown in FIG. 5A, the first bottom portion 141 of the first conduction layer 140 is located between the first conductive material 150 and the circuit layer 120. And in the second embodiment as shown in FIG. 5B, the first bottom portion 141 of the first conduction layer 140 is located between the first conductive material 150 and the conduction layer 110.

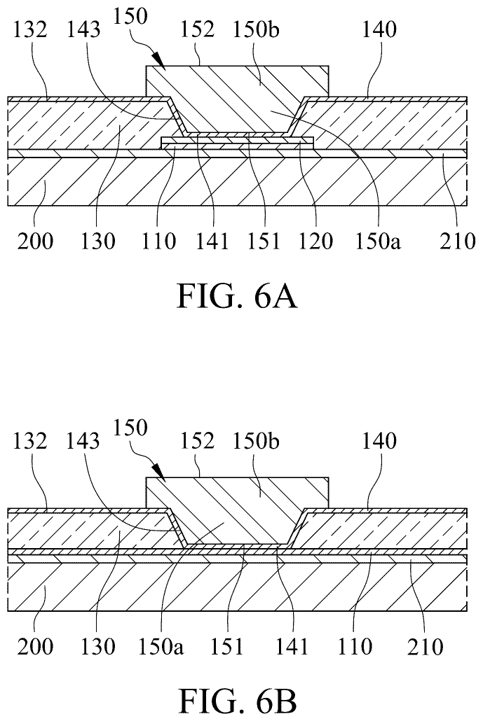

With reference to FIGS. 6A and 6B, the patterned first photoresist layer R1 is removed after forming the first conductive material 150. The second conductive portion 150b of the first conductive material 150 is visible and protrudes from the first top surface 132 of the first dielectric layer 130.

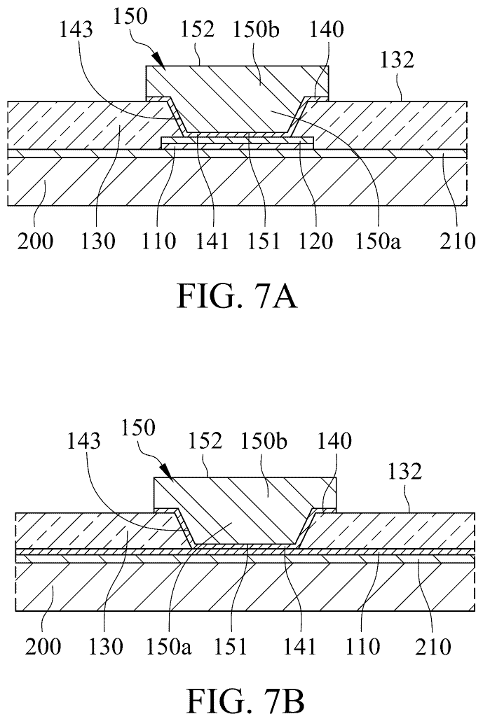

With reference to FIGS. 7A and 7B, after removing the patterned first photoresist layer R1, the first conduction layer 140 not covered by the first conductive material 150 is removed using the first conductive material 150 as a mask. Preferably, the first conduction layer 140 located on the first top surface 132 of the first dielectric layer 130 and not covered by the second conductive portion 150b of the first conductive material 150 is removed using the second conductive portion 150b as a mask.

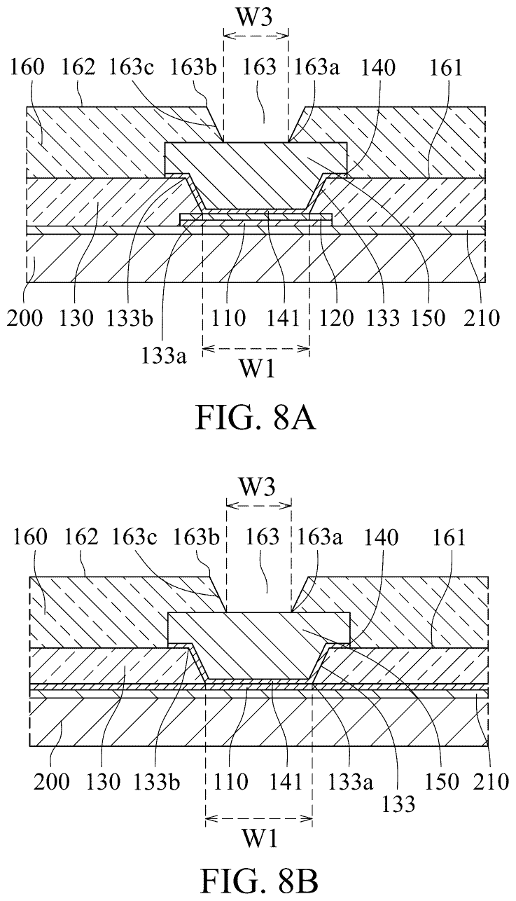

With reference to FIGS. 8A and 8B, next, the second dielectric layer 160 is formed to cover the first dielectric layer 130. Preferably, the second dielectric layer 160 also covers a part of the second conductive portion 150b of the first conductive material 150, thus the second conduction surface 152 located on the second conductive portion 150b is visible. The second dielectric layer 160 may be made of polyimide or other dielectric materials, and it may be formed by coating. The second dielectric layer 160 has at least one second through hole 163 formed through photolithography. The second through hole 163 is located above the first through hole 133 of the first dielectric layer 130, and the first conductive material 150 is visible from the second through hole 163.

With reference to FIGS. 8A and 8B, the second through hole 163 has a third opening 163a, a fourth opening 163b and a second ring wall 163c. The third opening 163a is located between the fourth opening 163b and the second opening 133b of the first dielectric layer 130, and it is adjacent to a second bottom surface 161 of the second dielectric layer 160. The fourth opening 163b is visible on a second top surface 162 of the second dielectric layer 160. The second ring wall 163c is located between the third opening 163a and the fourth opening 163b. Preferably, the second ring wall 163c located between the third opening 136a and the fourth opening 163b is oblique in cross-sectional view, and a width W3 of the third opening 163a is less than a width W1 of the first opening 133a.

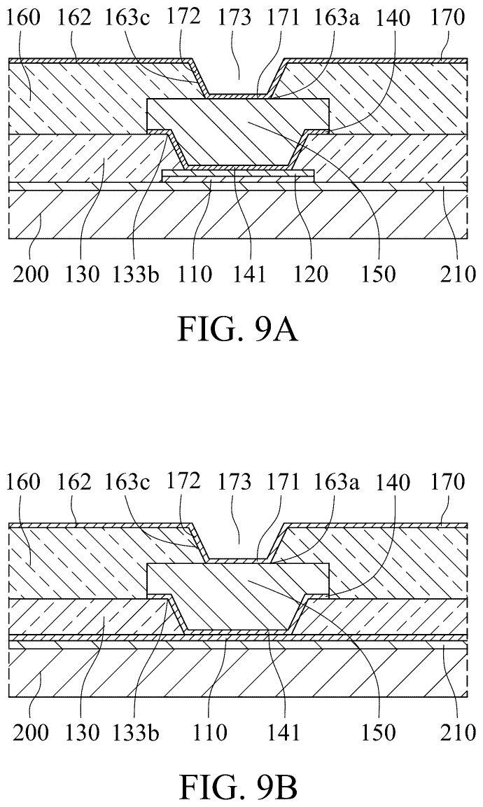

With reference to FIGS. 9A and 9B, after forming the second dielectric layer 160, the second conduction layer 170 is formed on the second top surface 162 of the second dielectric layer 160 and formed in the second through hole 163 of the second dielectric layer 160. The second conduction layer 170 may be deposited on the second dielectric layer 160 by sputtering. The second conduction layer 170 includes a second bottom portion 171, a second ring portion 172 and a second space 173. The second bottom portion 171 is in the third opening 163a and is electrically connected to the first conductive material 150, the second ring portion 172 is located on the second ring wall 163c and surrounds the second space 173. Preferably, the second ring portion 172 formed on the second ring wall 163c is oblique in cross-sectional view, and the first bottom portion 141 of the first conduction layer 140 has a larger area than the second bottom portion 171 of the second conduction layer 170.

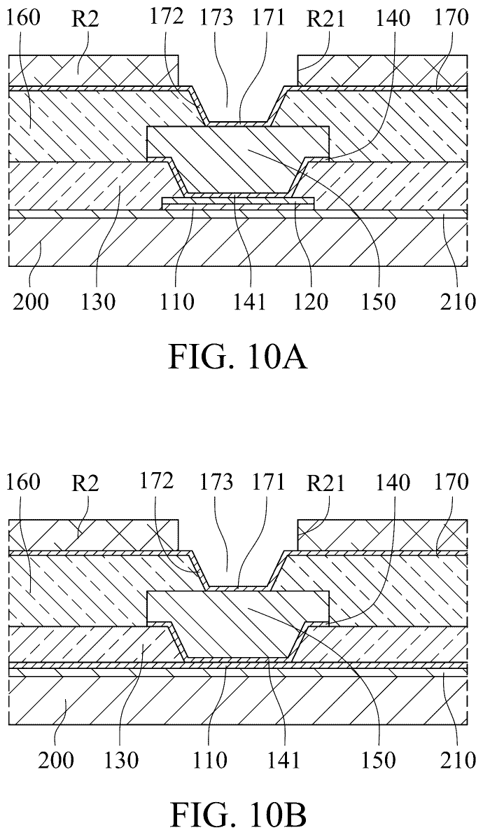

With reference to FIGS. 10A and 10B, after forming the second conduction layer 170, a second photoresist layer R2 is provided on the second conduction layer 170, and then the second photoresist layer R2 is patterned to have a second filling hole R21. The second bottom portion 171, the second ring portion 172 and the second space 173 of the second conduction layer 170 are visible from the second filling hole R21. Preferably, photoresist material is coated on the second conduction layer 170 to form the second photoresist layer R2 covering the second conduction layer 170, and the second photoresist layer R2 is patterned to form the second filling hole R21 through photolithography.

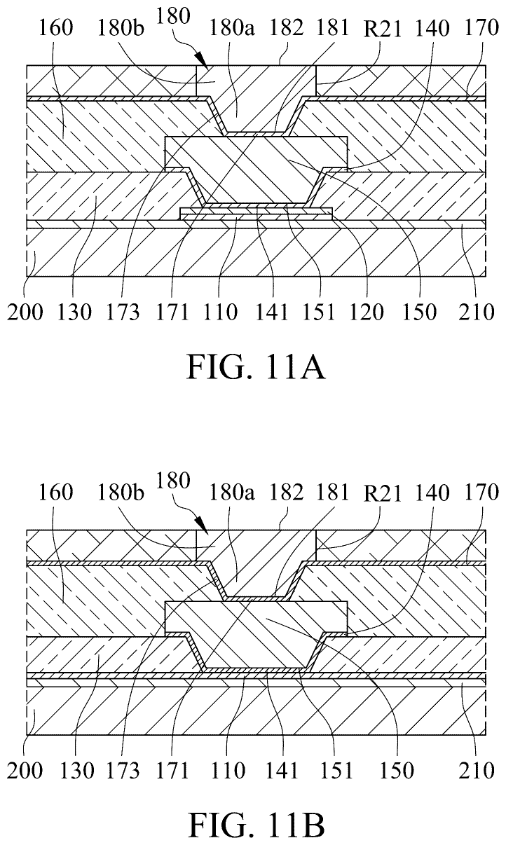

With reference to FIGS. 11A and 11B, after patterning the second photoresist layer R2, the second conductive material 180 is formed in the second space 173 of the second conduction layer 170. The second conductive material 180 may be a part of another redistribution layer (not shown) and may be deposited on the patterned second photoresist layer R2 by plating process. The second conductive material 180 has a third conduction surface 181 and a fourth conduction surface 182, the third conduction surface 181 is electrically connected to the second bottom portion 171 of the second conduction layer 170, and the area of the third conduction surface 181 of the second conductive material 180 is smaller than that of the first conduction surface 151 of the first conductive material 150. Preferably, the second conductive material 180 involves a third conductive portion 180a and a fourth conductive portion 180b, the third conductive portion 180a is located in the second space 173 of the second conduction layer 170, and the fourth conductive portion 180b is located in the second filling hole R21 of the patterned second photoresist layer R2.

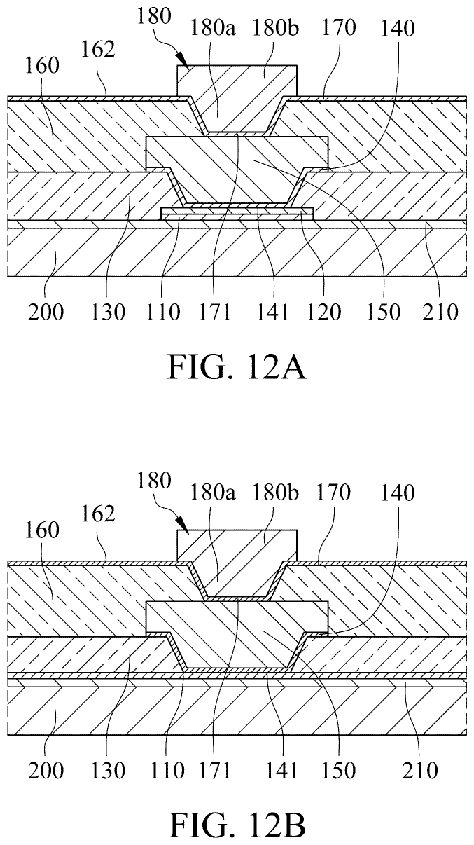

With reference to FIGS. 12A and 12B, the patterned second photoresist layer R2 is removed after forming the second conductive material 180. The fourth conductive portion 180b is visible and protrudes from the second top surface 162 of the second dielectric layer 160.

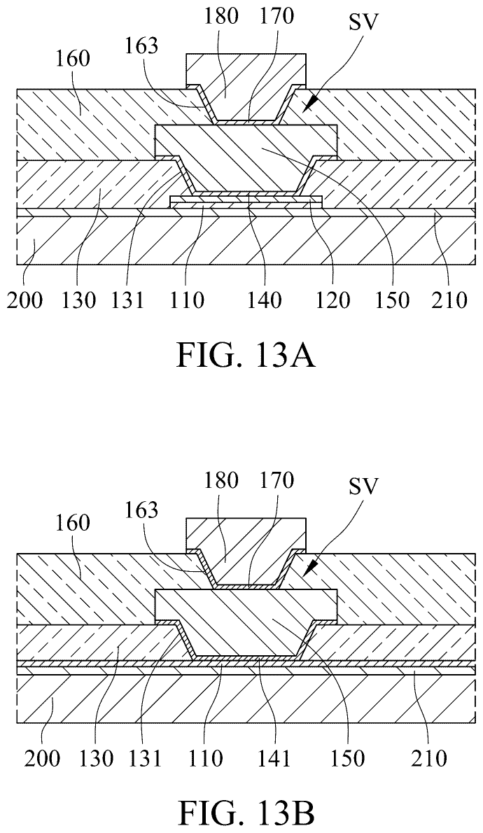

With reference to FIGS. 13A and 13B, after removing the patterned second photoresist layer R2, the second conduction layer 170 not covered by the second conductive material 180 is removed using the second conductive material 180 as a mask. The first conduction layer 140, the first conductive material 150, the second conduction layer 170 and the second conductive material 180 are stacked to become the stack via SV. Preferably, the second conduction layer 170 located on the second top surface 162 of the second dielectric layer 160 and not covered by the fourth conductive portion 180b of the second conductive material 180 is removed using the fourth conductive portion 180b as a mask.

With reference to FIGS. 14A and 14B, in final, the carrier 200 and the adhesive 210 are removed to obtain the substrate 100 having the stack via SV.

In the first embodiment as shown in FIG. 14A, after removing the carrier 200 and the adhesive layer 210, the conduction layer 110 and the circuit layer 120 are still left on the substrate 100, and the first bottom surface 131 of the first dielectric layer 130 and the conduction layer 110 are visible.

In the second embodiment as shown in FIG. 14B, the conduction layer 110 is also removed with the carrier 200 and the adhesive 210, thus the first bottom surface 131 of the first dielectric layer 130 and the first bottom portion 141 located in the first opening 133a are visible.

The stack via SV is formed through the method mentioned above, dielectric material for the second dielectric layer 160 will not be remained in the first space 143 of the first conduction layer 140, and dielectric material for further dielectric layer (not shown) will not be remained in the second space 173 of the second conduction layer 170 such that the second conduction layer 170 can be electrically connected to the first conductive material 150. Furthermore, contact area of the first conductive material 150 and the first conduction layer 140 and contact area of the second conductive material 180 and the second conduction layer 170 are large enough for requirements of electrical transmission, and the shapes of the first conductive material 150 and the second conductive material 180 can satisfy specification requirement.

While this invention has been particularly illustrated and described in detail with respect to the preferred embodiments thereof, it will be clearly understood by those skilled in the art that is not limited to the specific features shown and described and various modified and changed in form and details may be made without departing from the scope of the claims.

1. A method of manufacturing a substrate comprising:
forming a first dielectric layer which has a first bottom surface, a first top surface and a first through hole, the first through hole has a first opening, a second opening and a first ring wall, the first opening is adjacent to the first bottom surface, the second opening is visible on the first top surface, and the first ring wall is located between the first and second openings;
forming a first conduction layer on the first top surface of the first dielectric layer and in the first through hole of the first dielectric layer, the first conduction layer includes a first bottom portion, a first ring portion and a first space, the first bottom portion is in the first opening, the first ring portion is located on the first ring wall and surrounds the first space;
forming a first photoresist layer on the first conduction layer and patterning the first photoresist layer to form a first filling hole, the first bottom portion, the first ring portion and the first space of the first conduction layer are visible from the first filling hole;
forming a first conductive material in the first space of the first conduction layer, the first conductive material has a first conduction surface and a second conduction surface, and the first conduction surface is electrically connected to the first bottom portion of the first conduction layer;
removing the first photoresist layer;
using the first conductive material as a mask to remove the first conduction layer not covered by the first conductive material;
forming a second dielectric layer to cover the first dielectric layer, the second dielectric layer has a second bottom surface, a second top surface and a second through hole which is located above the first through hole of the first dielectric layer, the first conductive material is visible from the second through hole, the second through hole has a third opening, a fourth opening and a second ring wall, the third opening is located between the second opening of the first through hole and the fourth opening and is adjacent to the second bottom surface, the fourth opening is visible on the second top surface, the second ring wall is located between the third and fourth openings, and a width of the third opening is less than that of the first opening of the first through hole;
forming a second conduction layer on the second top surface of the second dielectric layer and in the second through hole of the second dielectric layer, the second conduction layer includes a second bottom portion, a second ring portion and a second space, the second bottom portion is located in the third opening of the second through hole and is electrically connected to the first conductive material, the second ring portion is located on the second ring wall and surrounds the second space;
forming a second photoresist layer on the second conduction layer and patterning the second photoresist layer to form a second filling hole, the second bottom portion, the second ring portion and the second space of the second conduction layer are visible from the second filling hole;
forming a second conductive material in the second space of the second conduction layer, the second conductive material has a third conduction surface and a fourth conduction surface, and the third conduction surface is electrically connected to the second bottom portion of the second conduction layer;
removing the second photoresist layer; and
using the second conductive material as a mask to remove the second conduction layer not covered by the second conductive material, wherein the first conduction layer, the first conductive material, the second conduction layer and the second conductive material form a stack via.

2. The method in accordance with claim 1, wherein an area of the first bottom portion of the first conduction layer is larger than that of the second bottom portion of the second conduction layer.

3. The method in accordance with claim 1, wherein an area of the first conduction surface of the first conductive material is larger than that of the third conduction surface of the second conductive material.

4. The method in accordance with claim 1, wherein a circuit layer is formed before forming the first dielectric layer, the circuit layer is visible from the first through hole of the first dielectric layer after forming the first dielectric layer, the first bottom portion of the first conduction layer is located between the first conductive material and the circuit layer and is electrically connected to the circuit layer.

5. The method in accordance with claim 4, wherein a conduction layer is formed before forming the circuit layer, the circuit layer is electrically connected to the conduction layer and is located between the first bottom portion of the first conduction layer and the conduction layer, and the conduction layer is visible on the first bottom surface of the first dielectric layer.

6. The method in accordance with claim 5, wherein a carrier having an adhesive layer is provided before forming the conduction layer, the conduction layer is formed on the adhesive layer, the carrier and the adhesive layer is removed after forming the stack via, and the first bottom surface of the first dielectric layer and the conduction layer are visible.

7. The method in accordance with claim 1, wherein a conduction layer is formed on an adhesive layer of a carrier before forming the first dielectric layer, the first dielectric layer is formed on the conduction layer, the conduction layer is located between the first bottom portion of the first conduction layer and the adhesive layer, the first bottom portion of the first conduction layer is located between the first conductive material and the conduction layer and is electrically connected to the conduction layer, the conduction layer is visible from the first through hole of the first dielectric layer, the carrier, the adhesive layer and the conduction layer are removed after forming the stack via, and the first bottom surface of the first dielectric layer and the first bottom portion located in the first opening are visible.

8. The method in accordance with claim 1, wherein the first ring wall located between the first and second openings is oblique, and the first ring portion of the first conduction layer formed on the first ring wall is oblique.

9. The method in accordance with claim 8, wherein the second ring wall located between the third and fourth openings is oblique, and the second ring portion of the second conduction layer formed on the second ring wall is oblique.

10. The method in accordance with claim 1, wherein the first conductive material includes a first conductive portion and a second conductive portion, the first conductive portion is located in the first space of the first conduction layer and the second conductive portion is located in the first filling hole of the first photoresist layer, the second conductive portion protrudes from the first top surface of the first dielectric layer after removing the first photoresist layer, and the first conduction layer located on the first top surface of the first dielectric layer and not covered by the second conductive portion is removed using the second conductive portion as a mask.

11. The method in accordance with claim 10, wherein the second conductive material includes a third conductive portion and a fourth conductive portion, the third conductive portion is located in the second space of the second conduction layer and the fourth conductive portion is located in the second filling hole of the second photoresist layer, the fourth conductive portion protrudes from the second top surface of the second dielectric layer after removing the second photoresist layer, and the second conduction layer located on the second top surface of the second dielectric layer and not covered by the fourth conductive portion is removed using the fourth conductive portion as a mask.

12. A substrate comprising:
a first dielectric layer having a first bottom surface, a first top surface and a first through hole, the first through hole has a first opening, a second opening and a first ring wall, the first opening is adjacent to the first bottom surface, the second opening is visible on the first top surface, and the first ring wall is located between the first and second openings;
a first conduction layer formed in the first through hole of the first dielectric layer and including a first bottom portion, a first ring portion and a first space, the first bottom portion is in the first opening of the first through hole, the first ring portion is located on the first ring wall and surrounds the first space;
a first conductive material formed in the first space of the first conduction layer and having a first conduction surface and a second conduction surface, the first conduction surface is electrically connected to the first bottom portion of the first conduction layer;
a second dielectric layer covering the first dielectric layer and having a second bottom surface, a second top surface and a second through hole, the second through hole is located above the first through hole of the first dielectric layer and has a third opening, a fourth opening and a second ring wall, the third opening is located between the second opening of the first through hole and the fourth opening and is adjacent to the second bottom surface, the fourth opening is visible on the second top surface, the second ring wall is located between the third and fourth openings, and a width of the third opening is less than that of the first opening of the first through hole;
a second conduction layer formed on the second top surface of the second dielectric layer and in the second through hole of the second dielectric layer, the second conduction layer includes a second bottom portion, a second ring portion and a second space, the second bottom portion is in the third opening of the second through hole and is electrically connected to the first conductive material, the second ring portion is located on the second ring wall and surrounds the second space; and
a second conductive material formed in the second space of the second conduction layer and having a third conduction surface and a fourth conduction surface, the third conduction surface is electrically connected to the second bottom portion of the second conduction layer, wherein the first conduction layer, the first conductive material, the second conduction layer and the second conductive material form a stack via.

13. The substrate in accordance with claim 12, wherein an area of the first bottom portion of the first conduction layer is larger than that of the second bottom portion of the second conduction layer.

14. The substrate in accordance with claim 12, wherein an area of the first conduction surface of the first conductive material is larger than that of the third conduction surface of the second conductive material.

15. The substrate in accordance with claim 12, wherein the first ring wall located between the first and second openings is oblique, and the first ring portion of the first conduction layer formed on the first ring wall is oblique.

16. The substrate in accordance with claim 15, wherein the second ring wall located between the third and fourth openings is oblique, and the second ring portion of the second conduction layer formed on the second ring wall is oblique.

17. The substrate in accordance with claim 12 further comprising a circuit layer, wherein the circuit layer is visible on the first bottom surface of the first dielectric layer, the first bottom portion of the first conduction layer is located between the first conductive material and the circuit layer and is electrically connected to the circuit layer.

18. The substrate in accordance with claim 17 further comprising a conduction layer, wherein the circuit layer is electrically connected to the conduction layer and is located between the first bottom portion of the first conduction layer and the conduction layer, and the conduction layer is visible on the first bottom surface of the first dielectric layer.

19. The substrate in accordance with claim 12, wherein the first bottom portion of the first conduction layer is visible on the first bottom surface of the first dielectric layer.

20. The substrate in accordance with claim 12, wherein the first conductive material includes a first conductive portion and a second conductive portion, the first conductive portion is located in the first space of the first conduction layer, the second conductive portion protrudes from the first top surface of the first dielectric layer, a part of the second conductive portion is covered by the second dielectric layer, and the second conduction surface located on the second conductive portion is visible.
